(19) United States
(12) Patent Application Publication
(10) Pub. No.: US 2013/0063898 A1
(43) Pub. Date: Mar. 14, 2013

(54) Heat-conducting system between two component parts and method for preparing a heat-conducting system

(71) Applicants: Klaus-Volker Schuett, Wernau (DE); Ruben Wahl, Kernen (DE)

(72) Inventors: Klaus-Volker Schuett, Wernau (DE); Ruben Wahl, Kernen (DE)

(21) Appl. No.: 13/636,315

(22) PCT Filed: Jan. 26, 2011
(86) PCT No.: PCT/EP11/51015

§ 371 Date: Nov. 28, 2012

(30) Foreign Application Priority Data
Mar. 26, 2010 (DE) 10 2010 003 330.8

(51) Int. Cl. H05K 7/20; H05K 13/00

(52) U.S. Cl. 361/704; 219/85.15

(57) ABSTRACT

A heat-conducting system has a heat-generating first component part and a second component part for dissipating the heat of the first component part, the two component parts being situated in operative connection to each other using a heat-conducting medium. The heat-conducting medium includes metal constituents, particularly metal ions, which are situated in a carrier material, especially in a polymer matrix; and the heat-conducting medium at an end state has dendrites made of the metal constituents, which are connected to the contact surfaces of the two component parts in a heat-conducting manner.

### BACKGROUND OF THE INVENTION

1. Field of the Invention

The present invention relates to a heat-conducting system between two component parts, and a method for preparing a heat-conducting system between two component.

2. Description of the Related Art

Such a system, or method for preparing such a system, is known from the related art. In this context, for example, a heat-generating first component part is connected to a heat-dissipating, second component part, such as a cooling element, via a medium. The medium, in this instance, is made up either of a paste, for example, which does not harden, as a so-called “gap filler, of which portions harden, or of a heat-conducting film or a heat-conducting adhesive substance, the two last-named media hardening fully, as a rule. The materials named are mostly filled up very highly by inorganic materials, such as silver, aluminum oxides, boron nitrides or carbon. In addition, there exist so-called “phase change materials” (PCM) whose aggregate state changes as a function of temperature, whereby an improvement is achieved in the wetting of the component parts. In the latest developments with respect to heat-conducting materials, nanoparticles (such as nanosilver, carbon nanotubes (CNT)) are used. All these materials are, however, critical, or rather not optimal with respect to a combination of the following requirements: High thermal conductivity at high flexibility, high thermal conductivity without the use of electrically conductive materials, high reduction in heat transfer resistance by a good thermal connection to the respective joining partner.

It is further known from U.S. Pat. No. 5,958,590 that one may use as soldering materials for connecting, or rather producing electrically conductive connections, dendritic powder materials having a high conductivity as paste. In this instance, electrically conductive metal particles are bound into a matrix of polymer material as the carrier material which, as long as the carrier material is not yet solid, form electrically conductive bridges, so-called “dendrites”, which assure a relatively low electrical resistance of the connection.

### BRIEF SUMMARY OF THE INVENTION

Starting from the related art shown, the present invention is based on the object of refining a heat-conducting system between two component parts and a method for preparing a heat-conducting system between two component parts, in such a way that the thermal connection between the two component parts is optimized with a view to the requirements named above. The present invention is based, in this instance, on the idea of enabling an optimum heat conductivity capability between the two component parts, that are in operative connection, by using a carrier material in which metal constituents are situated which form dendrites.

In order to make possible the formation of the dendrites, on the one hand, and to simplify the situation of the heat-conducting medium between the component parts, on the other hand, without this leading to difficulties or disadvantages during the operation, as a result of a liquid or pasty heat-conducting medium, it is provided in one preferred specific embodiment that the heat-conducting medium is developed to be liquid or pasty in a processing state and solid in a final state.

It is especially preferred that the two component parts, at least at the contact surfaces to the heat-conducting medium, are made of electrically conductive material, particularly of metal. This creates the possibility of enabling the targeted developed of the dendrites between the two contact surfaces, by applying a voltage, and a current flow that is connected with it, in the heat-conducting medium.

If the component parts that are to be connected in a heat-conducting manner are not made of metal, and the present invention is to be used, it is possible or conceivable in one variant of the present invention that the two component parts have a metallic coating at the contact surfaces, or a metallic layer.

In particular it is provided that the first component part is an electrical component part and the second component part is a cooling element. In this context, because of the heat-conducting system, an optimal heat flow is enabled between the electrical component part and the cooling element.

Furthermore, it is especially preferred that at least the heat-conducting medium is submitted to a heat treatment after the formation of the dendrites. Thereby, the desired fixed end state of the heat-conducting medium is achieved, which makes possible or assures a fixed connection of the heat-conducting medium to the contact surface of the two component parts.

In the case of an economically meaningful method for preparing the heat-conducting system, it is provided that the heat-conducting medium be applied to the contact surface of one of the two component parts, and that subsequently the other component part have its contact surface brought to installation contact with the heat-conducting medium.

In particular, it may be provided, in this instance, that applying the heat-conducting medium onto the contact surface of the one component part take place by stamping, dispensing or by screen printing. In this context, the method used will particularly depend on the surface condition or topography of the contact surface present of the first component part, as well as the size of same.

### BRIEF DESCRIPTION OF THE DRAWINGS

FIG. 1 shows a longitudinal section through a system of two heat-conducting component parts that are to be connected, using a heat-conducting medium in the initial state.

FIG. 2 shows a longitudinal section through the system according to FIG. 1, in which the system, or rather the heat-conducting medium has dendrites in the end state.

### DETAILED DESCRIPTION OF THE INVENTION

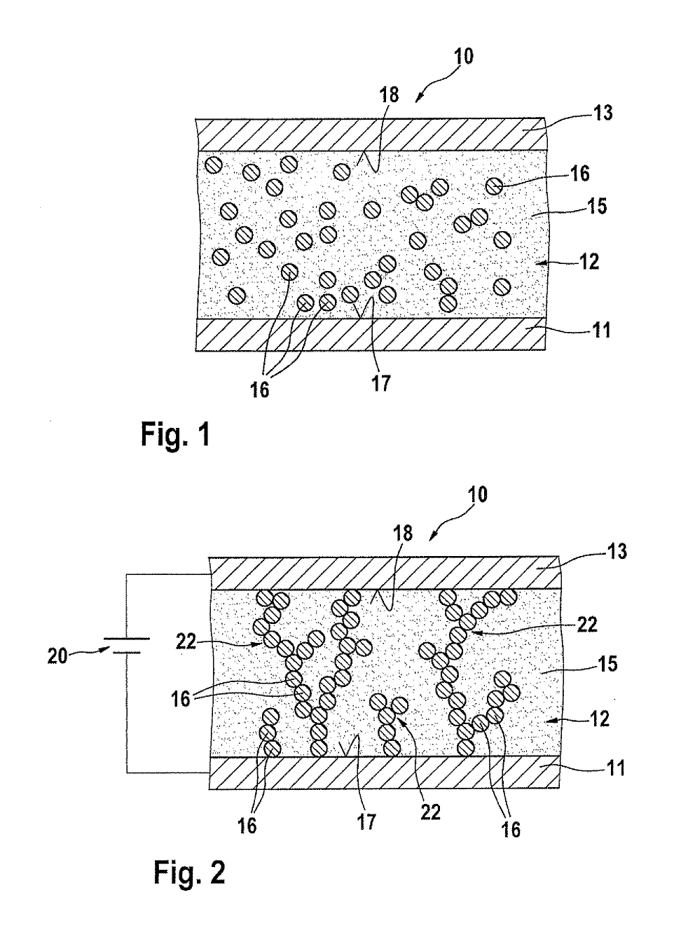

FIG. 1 shows a system 10, made up of a first component part 11, an heat-conducting medium 12 and a second component part 13. In this instance, first component part 11 may be, for example, but not restrictively, an heat-generating electrical or electronic component part, such as a power transistor, an IC or the like. Second component part 13, is in turn, for example, but not restrictively developed as a heat-dissipating component part, such as a cooling element, which is to give off the heat generated by first component part 11 to the surroundings.

The heat-conducting medium is made up of a carrier material 15, especially in the form of a polymer matrix, in which, in the initial state, as shown in FIG. 1, metal salts in the form of metal ions 16 are mixed in, which are situated more or less uniformly in carrier material 15. As metal ions 16, copper ions and/or iron ions and/or aluminum ions and/or silver ions are used. There is at first no contact, as a rule, between the individual metal ions 16, in this instance. It is also essential that heat-conducting medium 12 should be developed to be liquid or pasty, which makes the motion of metal ions 16 possible.

For preparing system 10, heat-conducting medium 12 is first mounted on first component part 11, for instance. This may be done particularly by stamping, dispensing or by screen printing, depending on economic or other requirements, which make it possible to apply heat-conducting medium 12 onto contact surface 17 of first component part 11 in the desired manner. Subsequently, second component part 13 is brought into operative connection to heat-conducting medium 12 with its contact surface 18 facing heat-conducting medium 12, for example, by pressing second component part 13 onto heat-conducting medium 12 using its contact surface 18.

After system 10 has been developed according to FIG. 1, an electric voltage is applied in a second step to the two component parts 11 and 13. This is illustrated in FIG. 2. In case the two component parts 11 and 13 are made of electrically conductive material, particularly of metal, such as copper, this is able to take place by the direct connection of component parts 11 and 13 to a voltage source 20. However, if the two component parts 11 and 13 are made of a material that conducts poorly electrically or not at all, it is advantageous or required that the two component parts 11 and 13 be provided at their contact surfaces 17 and 18 with a metallic coating or a metallic layer, such as one made of copper, which is then connected to voltage source 20.

By applying the voltage to the two component parts 11 and 13 (or to the electrically conductive contact surfaces 17 and 18 of the two component parts 11 and 13), metal ions 16 form dendrites 22, within heat-conducting medium 12, which enable direct connection between the two contact surfaces 17 and 18 via metal ions 16, and thus also between component parts 11 and 13. Consequently, the two contact surfaces 17 and 18 are directly connected by dendrites 22 in a heat-conducting manner, so that heat generated by first component part 11 is dissipated in a direct way via heat-conducting medium 12 or dendrites 22 to second component part 13.

Heat-conducting medium 12 hardens, or rather begins to harden, already when the voltage is applied and dendrites 22 form. To speed up the hardening process, it is meaningful and advantageous subsequently to submit system 10 to heat treatment in an oven. This will harden heat-conducting material 12 completely, so that an optimal heat conductivity is achieved.

System 10 shown and described up to this point may be adapted or modified in various ways. Thus, it is also conceivable, for example, that component parts 11 and 13 do not, as shown, have flat and smooth contact surfaces 17 and 18, but are developed differently. In this case, heat-conducting medium 12, because of its pasty or liquid form in its initial state, is able to fit snugly, without a problem, to the respective surfaces of component parts 11 and 13 and fill in gaps in the component parts.

1-10. (canceled)

11. A heat-conducting system, comprising:
a heat-generating first component part;
a second component part configured to dissipate the heat generated by the first component part; and
a heat-conducting medium operatively connecting the first and second component parts to each other;
wherein the heat-conducting medium includes dendrites made of metal constituents which are situated in a carrier material of a polymer matrix, and wherein the dendrites made of metal constituents are connected to contact surfaces of the first and second component parts in a heat-conducting manner.

12. The system as recited in claim 11, wherein the heat-conducting medium is solid.

13. The system as recited in claim 12, wherein at least the contact surfaces of the first and second component parts connected to the dendrites are made of electrically conducting material.

14. The system as recited in claim 13, wherein the first and second component parts have one of a metallic coating or a metallic layer at the contact surfaces.

15. The system as recited in claim 13, wherein the first component part is one of an electric or an electronic component part and the second component part is a cooling element.

16. A method for producing a heat-conducting device including two component parts and a heat-conducting medium positioned between contact surfaces of the two component parts, the method comprising:
applying an initial material for the heat-conducting medium on a contact surface of a first component part, wherein the initial material is in one of liquid form or paste form and includes metal constituents;
contacting a contact surface of a second component part with the initial material for the heat-conducting medium;
applying, at least indirectly, an electric voltage to the contact surfaces of the first and second component parts to form dendrites made of the metal constituents, wherein the dendrites connect the contact surfaces of the first and second component parts to each other in a heat-conducting manner; and
hardening the heat-conducting medium to form a soli.

17. The method as recited in claim 16, wherein at least the contact surfaces of the first and second component parts are configured to be electrically conducting to the heat-conducting medium.

18. The method as recited in claim 17, wherein after the formation of the dendrites, at least the heat-conducting medium is submitted to a heat treatment for the hardening.

19. The method as recited in claim 17, wherein the application of the initial material for the heat-conducting medium to the contact surface of the first component part takes place by one of stamping, dispensing or by screen printing.
